(19) United States
(12) Patent Application Publication
(10) Pub. No.: US 2025/0341685 A1
(43) Pub. Date: Nov. 6, 2025

(54) INTEGRATED TUNABLE BROADBAND SOURCE

(71) Applicant: University of Central Florida Research Foundation, Inc., Orlando, FL (US)

(72) Inventors: Darren Hudson, Orlando, FL (US); Andrea Blanco Redondo, Orlando, FL (US)

(73) Assignee: University of Central Florida Research Foundation, Inc., Orlando, FL (US)

(21) Appl. No.: 19/197,657

(22) Filed: May 2, 2025

Related U.S. Application Data
(60) Provisional application No. 63/641,985, filed on May 3, 2024.

(51) Int. Cl. G02B 6/42; G02B 6/032; H01S 5/00

(52) U.S. Cl. CPC G02B 6/4204; G02B 6/032; H01S 5/0085; G02B 2006/0325

(57) ABSTRACT

In accordance with at least one aspect of this disclosure, a tunable broadband source includes a first laser pump with a first tunability band width, a second laser pump with a second tunability band width, a pump combiner optically connected to receive laser illumination from the first laser pump and from the second laser pump and to output a combined illumination, and an integrated waveguide optically connected to receive the combined illumination from the pump combiner. The integrated waveguide is configured to output laser illumination tunable over a third tunability band width that is wider than either of the first tunability bandwidth or the second tunability bandwidth.

### CROSS REFERENCE TO RELATED APPLICATIONS

This application claims priority to U.S. Patent Application Ser. No. 63/641,985 filed May 3, 2024 which is incorporated herein by reference in its entirety.

### BACKGROUND

### 1. Field

The present disclosure relates to laser sources, and more particularly to on-chip laser emitters such as used in precision measurement, molecular detection, multi-spectral LIDAR, and the like.

### 2. Description of Related Art

Traditionally, on-chip laser emitters have used a single narrow-linewidth laser and a miniature circular resonator, known as a microcomb. While this traditional or conventional system allows for reasonably wide bandwidth coverage (hundreds of nanometers), the discrete lines are relatively fixed in their wavelength/frequency. Only by changing some parameter of the microcomb cavity, e.g., temperature, can the frequency of the emission lines be tuned. This limits the achievable wavelengths to a narrow range around the center frequencies of the discrete lines. A final complication of the conventional microcomb system is that the new wavelength content is typically quite inefficiently generated from the pump. It is not uncommon for the cascaded four-wave mixing (CFWM) lines to be more than 20 dB below the pump laser, i.e., one-hundred times weaker). This leads to fairly miniscule power in the discrete lines that are generated far from the pump wavelength, thus limiting applications and placing relatively severe requirements on photodetector technology.

The conventional techniques have been considered satisfactory for their intended purpose. However, there is an ever-present need for improved systems and methods for tunable broadband sources. This disclosure provides a solution for this need.

### SUMMARY

In accordance with at least one aspect of this disclosure, a tunable broadband source includes a first laser pump with a first tunability band width, a second laser pump with a second tunability band width, a pump combiner optically connected to receive laser illumination from the first laser pump and from the second laser pump and to output a combined illumination, and an integrated waveguide optically connected to receive the combined illumination from the pump combiner. The integrated waveguide is configured to output laser illumination tunable over a third tunability band width that is wider than either of the first tunability bandwidth or the second tunability bandwidth.

An optical path can be defined from the first and second laser pumps, through the pump combiner and the integrated waveguide to an optical outlet of the integrated waveguide. In certain embodiments, there is no microcomb resonator in the optical path. Tunability of the laser illumination output from the integrated waveguide can be a function of frequency offset of the first and second laser pumps. In certain embodiments, the integrated waveguide can include at least one air clad SiN waveguide body on a silica (SiO₂) substrate.

The first laser pump and the second laser pump can each include a respective semiconductor diode laser on a single integrated photonic device with the integrated waveguide and with the pump combiner. In certain embodiments, the single integrated photonic device can be a photonic chip. In certain embodiments, the tunable broadband source can further include a modulator to create pulses and an amplifier chain to create high peak power pulses.

In accordance with at least one aspect of this disclosures, a method can include combining illumination from a first laser pump and from a second laser bump on a single integrated photonic device, wherein each of the first laser pump and the laser pump is tunable over a first bandwidth, and outputting illumination from the single integrated photonic device that is tunable over an output bandwidth that is wider than the first bandwidth. In certain embodiments, the first bandwidth can be from 800 nm to 1900 nm wide, and the output bandwidth can be from about 1000 nm to about 2000 nm wide.

In certain embodiments, the first and second pump lasers can operate at an offset frequency in a range from 0 Hz to 10 THz. In certain embodiments, the output bandwidth is produced by cascaded four-wave mixing (CFWM) in a waveguide that is integrated into the single integrated photonic device with the first and second laser pumps.

These and other features of the systems and methods of the subject disclosure will become more readily apparent to those skilled in the art from the following detailed description taken in conjunction with the drawings.

### BRIEF DESCRIPTION OF THE DRAWINGS

So that those skilled in the art to which the subject disclosure appertains will readily understand how to make and use the devices and methods of the subject disclosure without undue experimentation, preferred embodiments thereof will be described in detail herein below with reference to certain figures, wherein:

FIG. 1 is a graph showing a representation of a principle of cascaded four-wave mixing (CFWM) in accordance with an exemplary embodiment of a system and method of this disclosure;

FIG. 2 is a schematic side elevation view of the waveguide of the system of FIG. 1;

FIG. 3 is a schematic plan view of the waveguide of FIG. 2;

FIG. 4 is a graph showing the dispersion profiles for one of the combinations of w and h in FIGS. 2-3, shown on a D versus wavelength plot;

FIG. 5 is a schematic representation of the system of FIGS. 2-3, showing the pumping lasers; and

FIG. 6 is a graph of results of a simulation showing cascaded four-wave mixing in an optimal dispersion waveguide.

### DETAILED DESCRIPTION

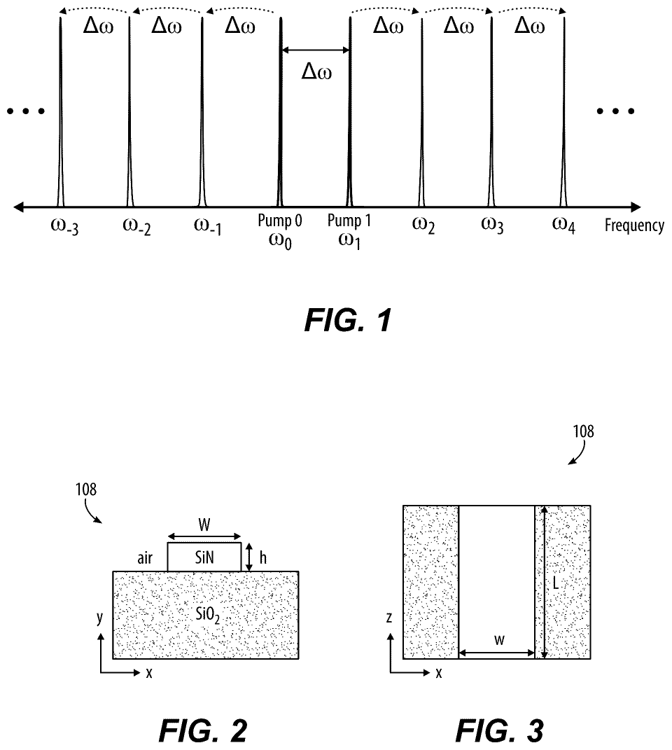

Reference will now be made to the drawings wherein like reference numerals identify similar structural features or aspects of the subject disclosure. For purposes of explanation and illustration, and not limitation, a partial view of an embodiment of a system in accordance with the disclosure is shown in FIG. 5. Other embodiments of systems in accordance with the disclosure, or aspects thereof, are provided in FIGS. 1-4 and 6, as will be described.

The system and method disclosed herein include a tunable broadband optical comb laser source in a chip-scale package, with applications ranging from molecular detection and sensing to telecommunications. The traditional method of creating such a laser emitter, the microcomb resonator, has major drawbacks including low tunability, low power, and inefficient wavelength conversion. The present disclosure eliminates the need for the resonator architecture and thereby significantly extends the power and functionality of the emitter. By employing integrated photonic fabrication technology, the current disclosure allows for incredibly low size, weight, and power while providing advanced functionality.

This disclosure details a method to create a broad spectrum of discrete narrow linewidth lasers. The application space for this technology is vast and includes precision measurement, molecular detection, multi-spectral lidar, and many others. A feature of the current disclosure is the compactness and versatility afforded by the active, integrated photonic platform.

In the disclosed system, the tunability limitation of traditional systems is removed, the need for advanced microcomb fabrication technology is eliminated, and dramatically improved conversion efficiency is provided. This is achieved by integrating two separate semiconductor diode lasers that are directly coupled to dispersion-engineered waveguides on the same integrated photonic device. The two pump lasers operate at an offset frequency (wavelength difference) that can be tuned from 0 Hz to >10 THz. Illumination from each of these two pump lasers combined into a single waveguide that has appropriate dispersion for cascaded four-wave mixing (CFWM) to occur. A typical scenario to achieve this is that the two lasers are symmetrically placed in frequency between two zero-dispersion (ZDW) points. New laser lines are created via four-wave mixing (FWM) at a spacing given by the original offset frequency between the two pump lasers. These new laser lines then repeat the process and create lines that further expand the spectrum. With optimized pumps and dispersion, this process can continue until the CFWM spectrum covers a large extent. While this depends on many parameters including the peak power of the pumps, dispersion of the waveguide, and the absorption spectrum of the nanophotonic medium, it is expected that spectral content greater than one octave can be achieved, e.g., greater than 1000-2000 nm. Furthermore, simulations show that the conversion efficiency when the two pump lasers are placed symmetrically between two ZDWs is dramatically improved. Indeed in many cases, lines far-detuned from the pump wavelength are equal in power to the pump after propagating through the dispersion engineered waveguide.

With reference now to FIG. 1, the graph shows under the principle of cascaded four-wave mixing, two strong pump lasers generate sidebands that cascade to higher and lower frequencies. With appropriate peak power and dispersion, the process can cascade over more than one octave of bandwidth, e.g., over more than 1000-2000 nm.

With reference to FIGS. 2-5, a tunable broadband source 100 is shown. The tunable broadband source 100 includes a first laser pump 102 with a first tunability band width, a second laser pump 104 with a second tunability band width and a pump combiner 106 optically connected to receive laser illumination from the first laser pump and from the second laser pump and to output a combined illumination. An integrated waveguide 108 is optically connected to receive the combined illumination from the pump combiner 106. The integrated waveguide 108 is configured to output laser illumination tunable over a third tunability band width that is wider than either of the first tunability bandwidth or the second tunability bandwidth.

An optical path 110 can be defined from the first and second laser pumps 102, 104, through the pump combiner 106 and the integrated waveguide 108 to an optical outlet 112 of the integrated waveguide 108. In certain embodiments, e.g., as shown, there is no microcomb resonator in the optical path 110. Tunability of the laser illumination output from the integrated waveguide 108 can be a function of frequency offset of the first and second laser pumps 102, 104. In certain embodiments, the integrated waveguide 108 can include at least one air clad SiN waveguide body on a silica (SiO₂) substrate (e.g., as detailed in FIG. 2).

The first laser pump 102 and the second laser pump 104 can each include a respective semiconductor diode laser 114, 116 on a single integrated photonic device 118 with the integrated waveguide 108 and with the pump combiner 106. In certain embodiments, the single integrated photonic device 118 can be a photonic chip. In certain embodiments, the tunable broadband source 100 can further include a modulator to create pulses and an amplifier chain to create high peak power pulses.

With continued reference to FIGS. 2 and 3, the waveguide 108 of this disclosure is shown schematically from a side elevation and plan view, respectively. Dispersion engineering relies on choosing the right materials and dimensions to create the desired dispersion profile. For this disclosure, dispersion engineering was performed on silicon nitride (SiN) waveguides. A set of SiN waveguides can be formed on a silica (SiO₂) substrate with air cladding. Those skilled in the art having had the benefit of this disclosure will readily appreciate that SiN is one suitable material, and that there is a wide range of other suitable semiconductors including but not limited to Si, SiC, Ge, AlGaAs, or the like, that can be used.

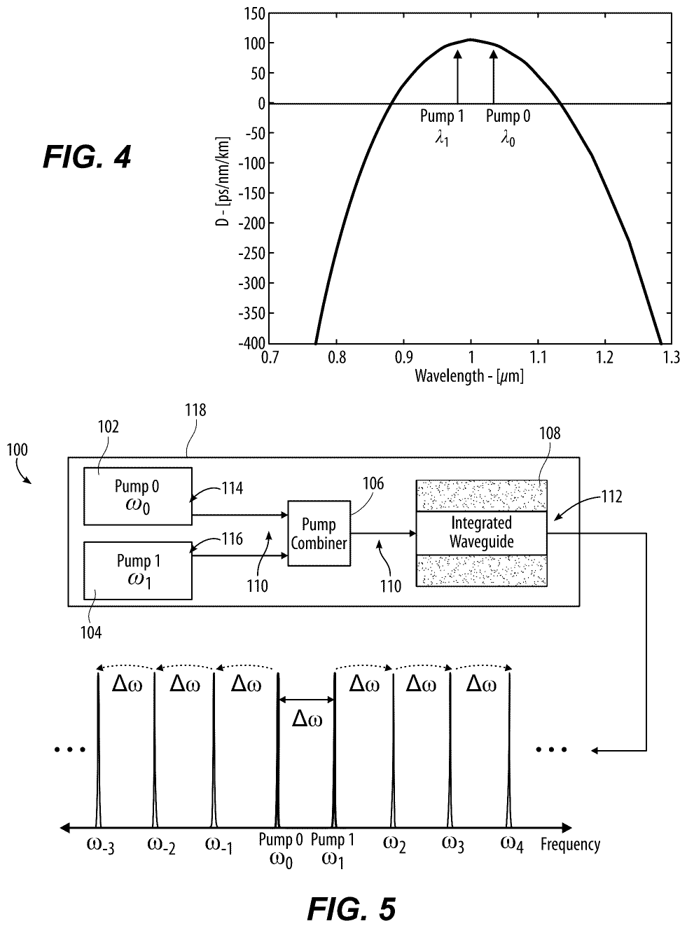

The appropriate combination of width (w) and height (h) can lead to optimal dispersion profiles as represented in the FIG. 1 for a given application. FIG. 4 shows the dispersion profile for one of those combinations of w and h on the D versus wavelength plot. The dispersion is positive around 1 μm and shows two zero-dispersion wavelength crossings at symmetric locations from this center wavelength.

In the device disclosed herein, the waveguide as schematically depicted in FIGS. 2-3 can be pumped with two pump lasers. FIG. 5 is a schematic representation of the system incorporating the integrated waveguide of FIGS. 2-3. The two laser pumps are combined and coupled into the integrated photonics waveguide with the desired dispersion profile, where the cascaded four wave mixing (CFWM) process occurs. FIG. 5 schematically shows the output illumination (or “new wavelength” content) of the system, which is also represented in FIG. 1.

Using a “dual-tone” pump, i.e., two separate laser wavelengths, it is possible to optimize four-wave mixing in a dispersion-engineered waveguide in a photonic chip platform. This process, which is shown in FIGS. 1 and 5, creates laser light at new wavelengths which maintain the original frequency spacing of the two pumps. FIG. 4 is a graph showing the optimal dispersion profile for pumping near 1030 nm, e.g. corresponding to FIGS. 1 and 5.

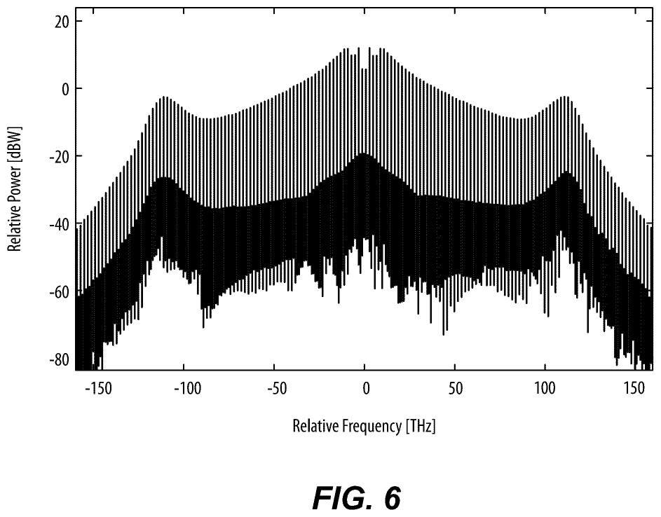

With reference now to FIG. 6, optimal fiber dispersion design for broadband cascade is described. FIG. 6 is representation of results of a simulation showing cascaded four-wave mixing (CFWM) in an optimal dispersion waveguide. In this case, the bandwidth exceeds 200 THz.

The systems and methods disclosed herein can provide potential benefits over traditional broadband sources, such as simplicity, tunability, conversion efficiency, and potentially maximum output power. Possible applications include spectroscopy, multi-spectral LIDAR, molecular detection (e.g. miniaturized molecular sensing), and the like. The traditional systems and methods exhibit very limited tunability and poor conversion efficiency between the pump laser and the “new wavelength” content. This disclosure directly solves problems in emerging commercial applications in precision metrology, sensing, and molecular detection. In these applications, traditional microcomb technologies have made a great impact, but still suffer from the problems mentioned above. Systems and methods in this disclosure can be used as a “light source” or “comb source” for a variety of applications such as those mentioned above. This can be useful in full system integrations and can use the light source technology as a better alternative to microcomb systems. With the integrated photonics platform of this system, a sensitive, broadband sensor can be realized in a package small enough to fit within a modern smartphone, for example.

An example of an embodiment uses a modulator and amplifier to create high peak power pulses to drive the CFWM more efficiently. Those skilled in the art will readily appreciate that this could be relaxed to include purely continuous wave (CW) laser systems operating at the Watt-level.

A method, e.g., using the tunable broadband source 100, can include combining illumination from a first laser pump (e.g., pump 102) and from a second laser pump (e.g., pump 104) on a single integrated photonic device (e.g. device 118), wherein each of the first laser pump and the laser pump is tunable over a first bandwidth, and outputting illumination from the single integrated photonic device that is tunable over an output bandwidth that is wider than the first bandwidth.

While the apparatus and methods of the subject disclosure have been shown and described with reference to preferred embodiments, those skilled in the art will readily appreciate that changes and/or modifications may be made thereto without departing from the scope of the subject disclosure.

What is claimed is:

1. A tunable broadband source comprising:
a first laser pump with a first tunability band width;
a second laser pump with a second tunability band width;
a pump combiner optically connected to receive laser illumination from the first laser pump and from the second laser pump and to output a combined illumination; and
an integrated waveguide optically connected to receive the combined illumination from the pump combiner, wherein the integrated waveguide is configured to output laser illumination tunable over a third tunability band width that is wider than either of the first tunability bandwidth or the second tunability bandwidth.

2. The tunable broadband source as recited in claim 1, wherein an optical path is defined from the first and second laser pumps, through the pump combiner and the integrated waveguide to an optical outlet of the integrated waveguide, wherein there is no microcomb resonator in the optical path.

3. The tunable broadband source as recited in claim 1, wherein tunability of the laser illumination output from the integrated waveguide is a function of frequency offset of the first and second laser pumps.

4. The tunable broadband source as recited in claim 1, wherein the integrated waveguide includes at least one air clad SiN waveguide body on a silica (SiO₂) substrate.

5. The tunable broadband source as recited in claim 4, wherein the first laser pump and the second laser pump each include a respective semiconductor diode laser on a single integrated photonic device with the integrated waveguide and with the pump combiner.

6. The tunable broadband source as recited in claim 5, wherein the single integrated photonic device is a photonic chip.

7. The tunable broadband source as recited in claim 1, further comprising a modulator to create pulses.

8. The tunable broadband source as recited in claim 7, further comprising an amplifier chain to create high peak power pulses.

9. A method comprising:
combining illumination from a first laser pump and from a second laser pump on a single integrated photonic device, wherein each of the first laser pump and the laser pump is tunable over a first bandwidth; and
outputting illumination from the single integrated photonic device that is tunable over an output bandwidth that is wider than the first bandwidth.

10. The method as recited in claim 9, wherein the first bandwidth is from 800 nm to 1900 nm wide.

11. The method as recited in claim 10, wherein the output bandwidth is from about 1000 nm to about 2000 nm wide.

12. The method as recited in claim 9, wherein the first and second pump lasers operate at an offset frequency in a range from 0 Hz to 10 THz.

13. The method as recited in claim 9, wherein the output bandwidth is produced by cascaded four-wave mixing (CFWM) in a waveguide that is integrated into the single integrated photonic device with the first and second laser pumps.
